(19) United States
(12) Patent Application Publication
(10) Pub. No.: US 2024/0128121 A1
(43) Pub. Date: Apr. 18, 2024

(54) MULTI-STEP PROCESS FOR FLOWABLE GAP-FILL FILM

(71) Applicant: Applied Materials, Inc., Santa Clara, CA (US)

(72) Inventors: Maximillian CLEMONS, Sunnyvale, CA (US); Nikolaos BEKIARIS, Campbell, CA (US); Srinivas D. NEMANI, Sunnyvale, CA (US)

(21) Appl. No.: 18/392,534

(22) Filed: Dec. 21, 2023

Related U.S. Application Data
(62) Division of application No. 16/792,646, filed on Feb. 17, 2020, now Pat. No. 11,901,222.

(51) Int. Cl. H01L 21/768; H01J 37/32; H01L 21/02

(52) U.S. Cl. CPC H01L 21/76837; H01J 37/32009; H01L 21/02271; H01J 2237/3321

(57) ABSTRACT

Generally, examples described herein relate to methods and processing systems for performing multiple processes in a same processing chamber on a flowable gap-fill film deposited on a substrate. In an example, a semiconductor processing system includes a processing chamber and a system controller. The system controller includes a processor and memory. The memory stores instructions, that when executed by the processor cause the system controller to: control a first process within the processing chamber performed on a substrate having thereon a film deposited by a flowable process, and control a second process within the process chamber performed on the substrate having thereon the film. The first process includes stabilizing bonds in the film to form a stabilized film. The second process includes densifying the stabilized film.

### CROSS-REFERENCE TO RELATED APPLICATIONS

This application is a divisional of co-pending U.S. patent application Serial No. U.S. Ser. No. 16/792,646, filed Feb. 17, 2020, which is herein incorporated by reference.

### BACKGROUND

### Field

Examples described herein generally relate to the field of semiconductor processing, and more specifically, to performing a multi-step process, e.g., in a same processing chamber, on a flowable gap-fill film on a substrate.

### Description of the Related Art

Reliably producing nanometer and smaller features is one of the technology challenges for next generation very large scale integration (VLSI) and ultra large-scale integration (ULSI) of semiconductor devices. As the limits of circuit technology are pushed, the shrinking dimensions of VLSI and ULSI technology have placed additional demands on processing capabilities. As the dimensions of the integrated circuit components are reduced (e.g., in nanometer dimensions), the materials and processes used to fabricate components are generally carefully selected in order to obtain satisfactory levels of electrical performance.

The reduced dimensions of integrated circuit components can lead to increasingly smaller gaps between components. Some processes that may have been suitable for filling similar gaps at larger dimensions may not be suitable to fill gaps at the smaller dimensions. Therefore, there is need for a process and processing system that is able to form complex devices at smaller dimensions while maintaining satisfactory performance of the devices of the integrated circuit.

### SUMMARY

Examples include a semiconductor processing system. The semiconductor processing system includes a processing chamber and a system controller. The system controller includes a processor and memory. The memory stores instructions, that when executed by the processor cause the system controller to: control a first process within the processing chamber performed on a substrate having thereon a film deposited by a flowable process, and control a second process within the process chamber performed on the substrate having thereon the film. The first process includes stabilizing bonds in the film to form a stabilized film. The second process includes densifying the stabilized film.

Examples also include a method for semiconductor processing. A substrate having thereon a film deposited by a flowable process is transferred into a processing chamber. A first process is performed, within the processing chamber, on the film on the substrate. The first process includes stabilizing bonds in the film to form a stabilized film. A second process is performed, within the processing chamber, on the film on the substrate. The second process includes comprising densifying the stabilized film.

Examples further include a non-transitory computer-readable storage medium storing instructions that, when executed by a processor, cause a computer system to perform operations. The operations include: controlling a processing system to perform a first process within a processing chamber of the processing system, and controlling the processing system to perform a second process within the process chamber. The first process is performed on a substrate having thereon a film deposited by a flowable process. The first process includes stabilizing bonds in the film to form a stabilized film. The second process is performed on the substrate having thereon the stabilized film. The second process includes comprising densifying the stabilized film.

### BRIEF DESCRIPTION OF THE DRAWINGS

So that the manner in which the above recited features of the present disclosure can be understood in detail, a more particular description, briefly summarized above, may be had by reference to examples, some of which are illustrated in the appended drawings. It is to be noted, however, that the appended drawings illustrate some examples and are therefore not to be considered limiting of the scope of this disclosure, for the disclosure may admit to other equally effective examples.

FIG. 1 shows a schematic top view of a multi-chamber processing system according to some examples.

FIG. 2 shows a schematic of a multi-pressure processing chamber that is configured to create a high pressure environment for processing and a low pressure environment for processing according to some examples.

FIGS. 3, 4, 5, and 6 show respective examples of a multi-pressure processing chamber according to some examples.

FIG. 7 is a flowchart of a method for semiconductor processing according to some examples.

FIGS. 8, 9, and 10 are cross-sectional views of intermediate semiconductor structures illustrating aspects of the method of FIG. 7 according to some examples.

To facilitate understanding, identical reference numerals have been used, wherever possible, to designate identical elements that are common to the figures.

### DETAILED DESCRIPTION

Generally, examples described herein relate to methods and processing systems for performing multiple processes in a same processing chamber on a flowable gap-fill film deposited on a substrate. The multiple process can include stabilizing bonds in a film deposited by a flowable process and subsequently densifying the film.

Performing example processes described herein on a flowable film can improve a quality of the film. Flowable films are commonly used for their ability to flow into gaps, particularly high aspect ratio gaps (e.g., having an aspect ratio of depth to width greater than 10:1). Flowable films generally have a poor quality, including a low density. Previous attempts have been made to increase the quality of flowable films, including processes that implement a hot water dip. These processes were implemented using multiple tools or processing chambers each implementing a different process. Even with these processes, it has been found that the quality of the film can remain poor. For example, a wet etch rate of the film can vary based on the depth of the etch in the film because of non-uniformity of, e.g., density throughout the film. Additionally, the wet etch rate, even varying, can be relatively high, which can cause any deviation of the etch rate to result in a significant difference in result. This can result in differing amounts of the film remaining in gaps. Examples described herein can improve quality of the film, such as improving density of the film. The improved density can achieve a more uniform and lower etch rate that can be more easily controlled and less susceptible to significant differences in results due to deviations from the etch rate. Further, less processing can be performed on the film to achieve such benefits, which can further reduce processing and queue time. Reduced processing and queue time can in turn reduce a cost to manufacture the end product. Additionally, a higher quality film can result in improved electrical characteristics in some applications. These and/or other benefits can be achieved according to various examples.

Various different examples are described below. Some examples are described herein in the context of forming isolation structures (e.g., shallow trench isolations (STIs)) between fins on a substrate. The isolation structures formed by such processing can be implemented in, for example, fin field-effect-transistors (FinFETs). These examples are provided for an understanding of various aspects. Other examples can be implemented in different contexts. For example, some examples can be implemented with any film deposited by a flowable process (e.g., flowable chemical vapor deposition (FCVD) or spin-on) on any underlying structure. Although multiple features of different examples may be described together in a process flow or system, the multiple features can each be implemented separately or individually and/or in a different process flow or different system. Additionally, various process flows are described as being performed in an order; other examples can implement process flows in different orders and/or with more or fewer operations.

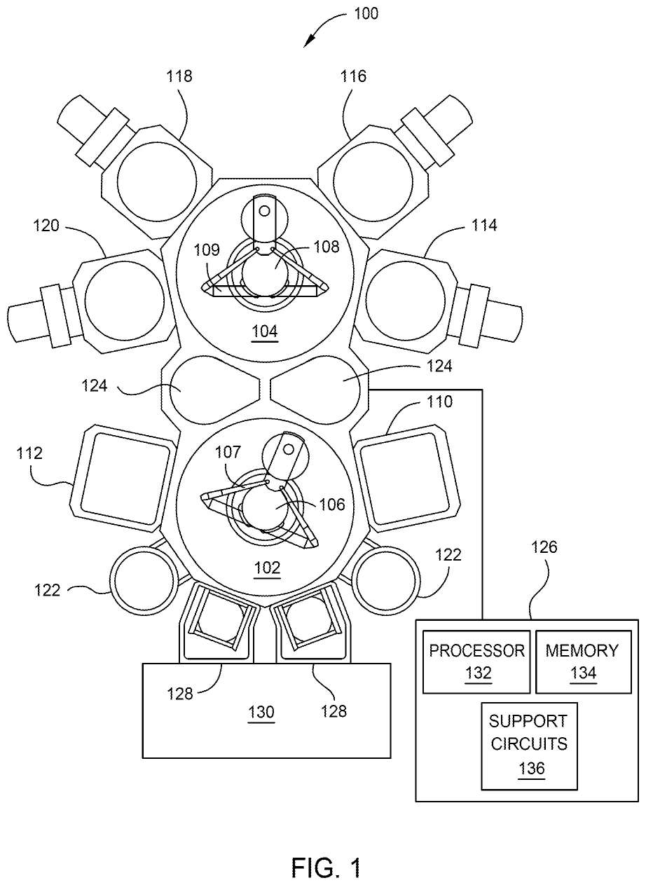

FIG. 1 shows a schematic top view of a multi-chamber processing system 100 according to some examples. In general, the multi-chamber substrate processing system includes at least one processing chamber that is configured to perform processes with different environments, such as with a high pressure and with a low pressure.

The processing system 100 includes two transfer chambers 102, 104; transfer robots 106, 108 positioned in the transfer chambers 102, 104, respectively; processing chambers 110, 112, 114, 116, 118, 120 disposed coupled to respective ones of the transfer chambers 102, 104; two degas chambers 122 disposed coupled to the first transfer chamber 102; pass-through chambers 124 disposed coupled to each of and between the two transfer chambers 102, 104; and a controller 126. The processing system 100 can further include load lock chambers 128 and a factory interface module 130.

The first transfer chamber 102 is a central vacuum chamber that interfaces with adjacent processing chambers 110, 112, and degas chambers 122. The first transfer chamber 102 is coupled with processing chambers 110, 112, the degas chambers 122, the pass-through chambers 124, and two load lock chambers 128. Each of the processing chambers 110, 112 and degas chambers 122 has an isolation valve disposed between the respective chamber and the first transfer chamber 102. The pass-through chambers 124 and load lock chambers 128 also have respective isolation valves disposed between the respective chamber 124, 128 and the first transfer chamber 102. Each isolation valve permits the respective chamber to be fluidly isolated from and fluidly connected to the first transfer chamber 102. The isolation valve of a chamber allows the respective chamber to operate at, e.g., a different level of pressure than the first transfer chamber 102 and prevents any gases being used in or introduced in the respective chamber from being introduced into the first transfer chamber 102. Each load lock chamber 128 has a door which opens to the outside environment, e.g., opens to the factory interface module 130.

The second transfer chamber 104 is a central vacuum chamber that interfaces with adjacent processing chambers 114, 116, 118, 120. The second transfer chamber 104 is coupled with processing chambers 114, 116, 118, 120 and the pass-through chambers 124. Each of the processing chambers 114, 116, 118, 120 has an isolation valve disposed between the respective chamber and the second transfer chamber 104. The pass-through chambers 124 also have respective isolation valves disposed between the respective chamber 124 and the second transfer chamber 104. Each isolation valve permits the respective chamber to be fluidly isolated from the second transfer chamber 104. The isolation valve of a chamber allows the respective chamber to operate at, e.g., a different level of pressure than the second transfer chamber 104 and prevents any gases being used in or introduced in the respective chamber from being introduced into the second transfer chamber 104.

The first transfer chamber 102 and the second transfer chamber 104 are separated by pass-through chambers 124, which may comprise cooldown or pre-heating chambers. The pass-through chambers 124 also may be pumped down or ventilated during substrate handling when the first transfer chamber 102 and the second transfer chamber 104 operate at different pressures.

While not shown, a gas and pressure control system (e.g., including a plurality of vacuum pumps) is disposed in fluid communication with each transfer chamber 102, 104, each pass-through chamber 124, and each of the processing and degas chambers 110-122 to independently regulate pressures in the respective chambers. The gas and pressure control system can include one or more gas pumps (e.g., turbo pumps, cryo-pumps, roughing pumps, etc.), gas sources, various valves, and conduits fluidly coupled to the various chambers. The gas and pressure control system is capable of maintaining any chamber at a target pressure.

The processing system 100 is automated by a controller 126 that is programmed to control operations, processes, or functions of the processing system 100. The controller 126 can operate individual operations for each of the chambers of the processing system 100 to process a substrate. For example, the controller 126 may control the operation of the processing system 100 using a direct control of the chambers 102-124 of the processing system 100 or by controlling controllers associated with the chambers 102-124. In operation, the controller 126 enables data collection and feedback from the respective chambers to coordinate performance of the processing system 100. The controller 126 generally can include a processor 132 (e.g., a central processing unit (CPU) or other processor), memory 134, and support circuits 136. The processor 132 may be one of any form of a general purpose processor that can be used in an industrial setting. The memory 134 (e.g., a non-transitory computer-readable storage medium) is accessible by the processor and may be one or more of memory such as random access memory (RAM), read only memory (ROM), floppy disk, hard disk, or any other form of digital storage, local or remote. The support circuits 136 can be coupled to the processor and may comprise cache, clock circuits, input/output subsystems, power supplies, and the like. The various methods disclosed herein may generally be implemented under the control of the processor 132 by the processor 132 executing computer instruction code stored in the memory 136 as, e.g., a software routine. When the computer instruction code is executed by the processor 132, the processor 132 controls the chambers to perform processes, and/or controls the processes within the chambers, in accordance with the various methods.

Substrates (not shown) are loaded into the processing system 100 through load lock chambers 128. For example, a factory interface module 130, if present, would be responsible for receiving one or more substrates, e.g., wafers, cassettes of wafers, or enclosed pods of wafers, from either a human operator or an automated substrate handling system. The factory interface module 130 can open the cassettes or pods of substrates, if applicable, and move the substrates to and from the load lock chambers 128. The first transfer chamber 102 receives the substrates from the load lock chambers 128, and the substrates can be transferred throughout the transfer chambers 102, 104, including via the pass-through chambers 124. The various chambers 110-122 receive the substrates from the transfer chambers 102, 104, process the substrates, and allow the substrates to be transferred back into the transfer chambers 102, 104.

In normal operation, a cassette loaded with substrates is placed into the load lock chamber 128 through the door from the factory interface module 130 and the door is closed. The load lock chamber 128 is then evacuated to the same pressure as the first transfer chamber 102 and the isolation valve between the load lock chamber 128 and the first transfer chamber 102 is opened. The transfer robot 106 in the first transfer chamber 102 is moved into position and one substrate is removed from the load lock chamber 128. The load lock chamber 128 is preferably equipped with an elevator mechanism so as one substrate is removed from the cassette, the elevator moves the stack of wafers in the cassette to position another wafer in the transfer plane so that it can be positioned on the robot blade.

The transfer robot 106 in the first transfer chamber 102 then rotates with the substrate so that the substrate is aligned with a processing chamber position. The processing chamber is flushed of any toxic gases, brought to the same pressure level as the transfer chamber, and the isolation valve between the processing chamber and the first transfer chamber 102 is opened. The transfer robot 106 then moves the wafer into the processing chamber where it is lifted off the transfer robot 106. The transfer robot 106 is then retracted from the processing chamber and the isolation valve is closed. The processing chamber then goes through a series of operations to execute a specified process on the wafer. When complete, the processing chamber is brought back to the same environment as the first transfer chamber 102 and the isolation valve is opened. The transfer robot 106 removes the wafer from the processing chamber and then either moves it to another processing chamber for another operation, moves it to the pass-through chamber 124 for transfer to the second transfer chamber 104, or replaces it in the load lock chamber 128 to be removed from the processing system 100 when the entire cassette of wafers has been processed.

If the transfer robot 106 moves the substrate to the pass-through chamber 124, transfer robot 106 in the first transfer chamber 102 rotates with the substrate so that the substrate is aligned with the pass-through chamber 124 position. The pass-through chamber 124 is brought to the same pressure level as the transfer chamber, and the isolation valve between the pass-through chamber 124 and the first transfer chamber 102 is opened. The transfer robot 106 then moves the wafer into the pass-through chamber 124 where it is lifted off the transfer robot 106. The transfer robot 106 is then retracted from the pass-through chamber 124 and the isolation valve is closed. The pass-through chamber 124 then can be brought to the same environment, such as including pressure, as the second transfer chamber 104. When the pass-through chamber 124 is brought back to the same environment as the second transfer chamber 104, the isolation valve between the pass-through chamber 124 and the second transfer chamber 104 is opened. The transfer robot 108 removes the wafer from the pass-through chamber 124, and the isolation valve is closed. The transfer robot 108 then moves the substrate to another processing chamber coupled to the second transfer chamber 104 for another operation. The transfer robot 108 can move the substrate to another processing chamber coupled to the second transfer chamber 104 like described above with respect to the transfer robot 108 moving the substrate to process chamber coupled to the first transfer chamber 102.

The transfer robot 108 can then move the substrate to the pass-through chamber 124 for transfer to the first transfer chamber 102, such as by a reverse sequence of operations by which the substrate was received in the second transfer chamber 104 through the pass-through chamber 124. The transfer robot 106 in the first transfer chamber 102 can move the substrate to another processing chamber for another operation or can replace it in the load lock chamber 128 to be removed from the processing system 100 when the entire cassette of wafers has been processed. The transfer robots 106, 108 include robot arms 107, 109, respectively, that support and move the substrate between different processing chambers.

The processing chambers 110-120 can be or include any appropriate processing chamber. One or more of the processing chambers 110-120 is a chamber configured to perform processing on a substrate using different environments, such as with different pressures, etc., in the chamber. Various examples are described below. Other example processing chambers for the processing chambers 110-120 include a chemical vapor deposition (CVD) chamber, an atomic layer deposition (ALD) chamber, a reactive ion etch (RIE) chamber, a rapid thermal anneal (RTA) or rapid thermal process (RTP) chamber, of the like.

Other processing systems can be in other configurations. For example, more or fewer processing chambers may be coupled to a transfer apparatus. In the illustrated example, a transfer apparatus includes the transfer chambers 102, 104 and pass-through chambers 124. In other examples, fewer or more transfer chambers, pass-through chambers, and/or one or more holding chambers may be implemented as a transfer apparatus in a processing system.

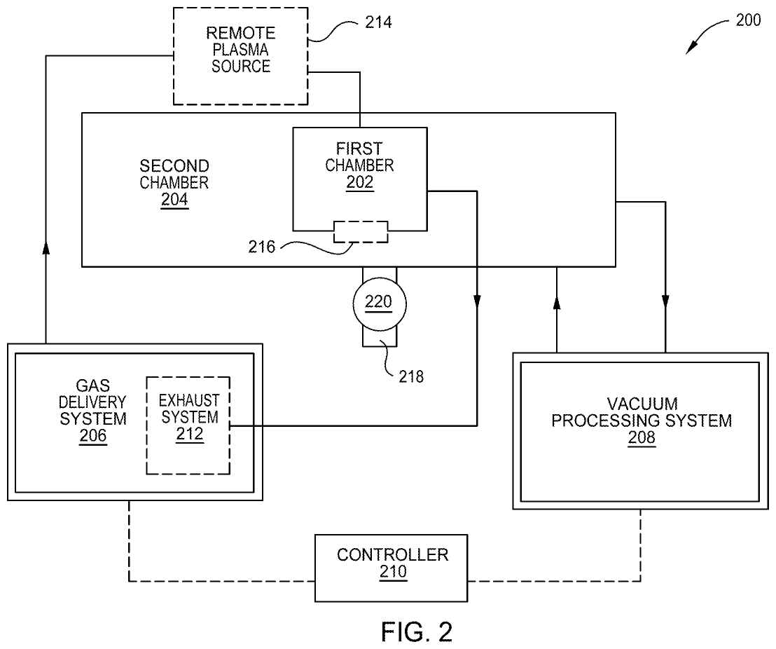

FIG. 2 illustrates a schematic of a multi-pressure processing chamber 200 that is configured to create a high pressure environment for processing a substrate and a low pressure environment for processing the substrate. The multi-pressure processing chamber 200 includes a first chamber 202 and a second chamber 204. The first chamber 202 is disposed within the second chamber 204 and may be considered an inner chamber, and the second chamber 204 may be considered an outer chamber. Further, as apparent from the following description, the first chamber 202 can be configured to enable high pressure processing and may further be considered a high pressure chamber. The first chamber 202 and second chamber 204 may, in some instances, be fluidly coupled together and configured to enable low pressure processing. The pressure within the first chamber 202 can be controlled independently of the pressure in the second chamber 204.

The controlled multi-pressure processing chamber 200 further includes a gas delivery system 206, a vacuum processing system 208, and a controller 210. In some examples, the gas delivery system 206 and the vacuum processing system 208 are at least part of the gas and pressure control system of the processing system 100 of FIG. 1. In some examples, the controller 126 of the processing system 100 can be or include the controller 210.

The gas delivery system 206 is fluidly coupled, e.g., by gas flow conduits, to the first chamber 202 and is operable to pressurize and depressurize the first chamber 202. The first chamber 202 is a high pressure processing chamber that receives a process gas from the gas delivery system 206 and establishes a high pressure, e.g., at a pressure of at least 1 Bar. The process gas can be or include oxygen gas (O₂), ozone gas (O₃), nitrous oxide (N₂O), nitric oxide (NO), steam (H₂O), ammonia gas (NH₃) the like, or a combination thereof. The gas delivery system 206 can include a combination of a gas panel, conduits, and valves that are controllable, e.g., by the controller 210 to deliver process gases to the first chamber, which may have different process gas compositions for different processes performed in the multi-pressure processing chamber 200. To pressurize the first chamber 202, the gas delivery system 206 introduces the process gas into the first chamber 202. The gas delivery system 206 can include an exhaust system 212 to exhaust the process gas from the first chamber 202, thereby depressurizing the first chamber 202.

In some implementations, the multi-pressure processing chamber 200 includes a remote plasma source (RPS) 214. The RPS 214, in such implementations, is fluidly coupled, e.g., by gas flow conduits, to the gas delivery system 206. The RPS 214 is further fluidly coupled to the first chamber 202. Process gases flowing from the gas delivery system 206 can be ignited in a plasma in the RPS 214. Effluents from the plasma in the RPS 214 can flow into the first chamber 202. The RPS 214 can be a capacitively coupled plasma source or inductively coupled plasma source, for example.

The vacuum processing system 208 is fluidly coupled, e.g., by gas flow conduits, to the second chamber 204 and is operable to control the pressure of the second chamber 204 to be at low pressure, such as at a vacuum or near-vacuum pressure. The low pressure can be, e.g., as low as 10 milliTorr. For example, the vacuum processing system 208 lowers a pressure within the second chamber 204 to near vacuum, thereby creating the appropriate low pressure environment for processing a substrate.

A valve assembly 216 is disposed between the first chamber 202 and the second chamber 204 and is configured to isolate the pressure within the first chamber 202 from the pressure within the second chamber 204. The high pressure environment within the first chamber 202 can thus be separated and sealed from the environment within the second chamber 204. The valve assembly 216 is openable to fluidly connect the first chamber 202 to the second chamber 204 and/or to enable the substrate to be transferred from the multi-pressure processing chamber 200.

In some implementations, the multi-pressure processing chamber 200 includes a foreline 218 connected to the multi-pressure processing chamber 200, and connected to an outside environment. An isolation valve 220 is arranged along the foreline 218 to isolate the pressure within the second chamber 204 from the pressure of the outside environment. The isolation valve 220 can be operated to adjust the pressure within the second chamber 204 and to release gases within the second chamber 204. The isolation valve 220 can be operated in conjunction with the vacuum processing system 208 to regulate the pressure within the second chamber 204.

Generally, a substrate can be processed by multiple processes while disposed within the first chamber 202 within the multi-pressure processing chamber 200. For example, the substrate can be transferred to a pedestal (not shown) within the first chamber 202. The transfer of the substrate into the first chamber 202 can be through the valve assembly 216 in some examples. With the substrate disposed on the pedestal in the first chamber 202, the valve assembly 216 can remain open fluidly coupling the inner volume of the first chamber 202 with the inner volume of the second chamber 204. The vacuum processing system 208 can therefore pump down the pressure within the first chamber 202 and the second chamber 204 while the valve assembly 216 is open. Low pressure processing can therefore be performed on the substrate while the substrate is disposed on the pedestal in the first chamber 202. The low pressure processing can include flowing a process gas from the gas delivery system 206 into the first chamber 202, which can be evacuated by the vacuum processing system 208. In some examples, the low pressure processing can include using a plasma ignited in the RPS 214.

Additionally, with the substrate disposed on the pedestal in the first chamber 202, the valve assembly 216 can be closed to fluidly isolate the inner volume of the first chamber 202 from the inner volume of the second chamber 204. The gas delivery system 206 can create a high pressure within the first chamber 202 with the valve assembly 216 closed. High pressure processing can therefore be performed on the substrate while the substrate is disposed on the pedestal in the first chamber 202. The high pressure processing can include flowing a process gas from the gas delivery system 206 into the first chamber 202. In some examples, the high pressure processing can include using a plasma ignited in the RPS 214.

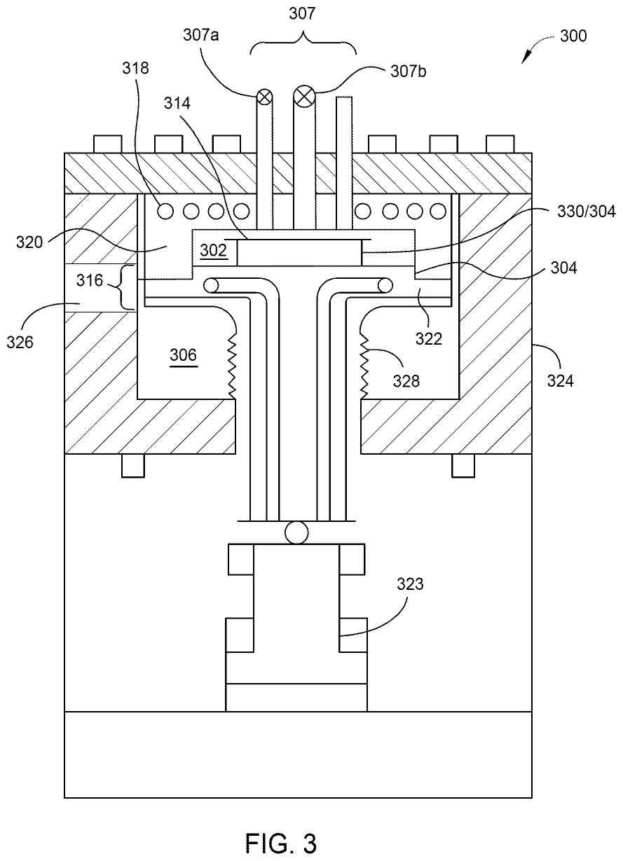

FIGS. 3 through 6 depict various examples of multi-pressure processing chambers for processing a substrate. The pressure of chambers of these multi-pressure processing chambers can be controlled using systems similar to those described with respect to FIG. 2.

Referring to FIG. 3, a multi-pressure processing chamber 300 includes a first chamber 302, a pedestal 304, a second chamber 306, and a controller (e.g., the controller 126). As apparent from the following description, the first chamber 302 is disposed within the second chamber 306 and may be considered an inner chamber, and the second chamber 306 may be considered an outer chamber. Further, as apparent from the following description, the first chamber 302 can be configured to enable high pressure processing and may further be considered a high pressure chamber. The first chamber 302 and second chamber 306 may, in some instances, be fluidly coupled together and configured to enable low pressure processing.

The multi-pressure processing chamber 300 further includes a vacuum processing system (not shown) similar to the vacuum processing system 208 and a gas delivery system 307 similar to the gas delivery system 206 described with respect to FIG. 2. For example, the gas delivery system 307 includes an input line 307a and an exhaust line 307b. The process gas is introduced into the first chamber 302 through the input line 307a, and the process gas is exhausted from the first chamber 302 through the exhaust line 307b. In some examples, the multi-pressure processing chamber 300 can include an RPS, which may be coupled to the input line 307a for flowing plasma effluents from the RPS into the first chamber 302.

The pedestal 304 supports a substrate 314 on which a film is to be processed. The pedestal 304 is positioned or positionable within the first chamber 302. In some implementations, the substrate 314 sits directly on a flat top surface of the pedestal. In some implementations, the substrate 314 sits on pins 330 that project from the pedestal.

The multi-pressure processing chamber 300 includes an inner wall 320, a base 322, and an outer wall 324. The first chamber 302 is provided by a volume within the inner wall 320 and the base 322. The second chamber 306 is provide by a volume within the inner wall 320 and outside the inner wall 320, e.g., between the inner wall 320 and the outer wall 324.

The multi-pressure processing chamber 300 further includes a valve assembly 316 between the first chamber 302 and the second chamber 306 that provides the functionality of the valve assembly 216 of FIG. 2, e.g., it can be operated to isolate the first chamber 302 from the second chamber 306 and to fluidly couple the first chamber 302 and the second chamber 306. For example, the valve assembly 316 includes the inner wall 320, the base 322, and an actuator 323 to move the base 322 relative to the inner wall 320. The actuator 323 can be controlled to drive the base 322 to move vertically, e.g., away from or toward the inner walls 320 defining the first chamber 302. A bellows 328 can be used to seal the second chamber 306 from the external atmosphere while permitting the base 322 to move vertically. The bellows 328 can extend from a bottom of the base 322 to a floor of the second chamber 306 formed by the outer wall 324.

When the valve assembly 316 is in a closed position, the base 322 contacts the inner walls 320 such that a seal is formed between the base 322 and the inner walls 320, thus separating the second chamber 306 from the first chamber 302. The actuator 323 is operated to drive the base 322 toward the inner walls 320 with sufficient force to form the seal. The seal inhibits gas from the first chamber 302 from being exhausted into the second chamber 306.

When the valve assembly 316 is in an open position, the base 322 is spaced apart from the inner walls 320, thereby allowing gas to be conducted between the first chamber 302 and second chamber 306 and also allowing the substrate 314 to be accessed and transferred to another chamber.

Because the pedestal 304 is supported on the base 322, the pedestal 304 is thus also movable relative to the inner walls 320. The pedestal 304 can be moved to enable the substrate 314 to be more easily accessible by the transfer robot. For example, an arm of a transfer robot 106 or 108 (see FIG. 1) can extend through an aperture 326 (e.g., a slit) through the outer wall 324. When the valve assembly 316 is in the open position, the robot arm can pass through the gap between the inner wall 320 and the base 322 to access the substrate 314 on the pedestal 304.

In some implementations, the multi-pressure processing chamber 300 includes one or more heating elements 318 configured to apply heat to the substrate 314. The heat from the heating elements 318 can be sufficient to, e.g., anneal the substrate 314 when the substrate 314 is supported on the pedestal 304 and the process gas (if used) has been introduced into the first chamber 302. The heating elements 318 may be resistive heating elements. The one or more heating elements 318 may be positioned in, e.g., embedded in, the inner walls 320 defining the first chamber 302, such as in a ceiling of the first chamber 302 provided by the inner walls 320. The heating elements 318 are operable to heat the inner wall 320, causing radiative heat to reach the substrate 314. The substrate 314 can be held by the pedestal 304 in close proximity, e.g., 2-10 mm, to the ceiling to improve transmission of heat from the inner wall 320 to the substrate 314.

The one or more heating elements 318 may be arranged in other locations within the multi-pressure processing chamber 300, e.g., within the side walls rather than the ceiling. An example of a heating element 318 includes a discrete heating coil. Instead of or in addition to a heater embedded in the inner wall, a radiative heater, e.g., an infrared lamp, can be positioned outside the first chamber 302 and direct infrared radiation through a window in the inner wall 320. Electrical wires connect an electrical source (not shown), such as a voltage source, to the heating element, and can connect the one or more heating elements 318 to the controller.

The controller is operably connected to the vacuum processing system, the gas delivery system 307, and the valve assembly 316 for controlling operations to process the substrate 314. In some implementations, the controller may also be operably connected to other systems. In some cases, the controller 126 shown in FIG. 1 is or includes the controller of the multi-pressure processing chamber 300.

In processing the substrate 314, the controller can operate the vacuum processing system to depressurize the second chamber 306 to a low pressure to prepare for transfer of the substrate 314 through the second chamber 306. The substrate 314 is moved through the aperture 326 and the second chamber 306 by a transfer robot, e.g., one of the transfer robots 106, 108, while the second chamber 306 is at the low pressure so that contamination of the substrate 314 can be inhibited.

The substrate 314 is transferred onto the pedestal 304 for processing. To transfer the substrate 314 onto the pedestal 304, the controller can operate the valve assembly 316 to open the valve assembly 316 to provide an opening through which the substrate 314 can be transferred into the first chamber 302 and onto the pedestal 304. The controller can operate the transfer robot to carry the substrate 314 into the first chamber 302 and to place the substrate 314 on the pedestal 304.

After the substrate 314 is transferred onto the pedestal 304, the controller can operate the valve assembly to be open for low pressure processing or closed for high pressure processing. Any order of high pressure processing and low pressure processing can be implemented. In some examples, a substrate can be processed by cyclically performing low pressure and high pressure processing.

With the valve assembly 316 closed, the inner volume of the first chamber 302 is isolated from the inner volume of the second chamber 306. With the valve assembly 316 closed, pressures in the first chamber 302 and the second chamber 306 can be set to different values. The controller can operate the gas delivery system 307 to introduce the process gas into the first chamber 302 to pressurize the first chamber 302 and to process the substrate 314. The introduction of the process gas can increase the pressure within the first chamber 302 to, for example, 1 Bar or more. Processing in the first chamber 302 can be at a high pressure. If implemented, plasma effluents can be introduced into the first chamber 302 from an RPS to process the substrate 314 during high pressure processing.

The controller can operate the valve assembly 316 to open the valve assembly 316, thereby having the first chamber 302 and second chamber 306 be in fluid communication with each other. With the valve assembly 316 open, pressures in the first chamber 302 and the second chamber 306 can be equal. The controller can operate the vacuum processing system to bring the first chamber 302 and second chamber 306 to a low pressure to process the substrate 314. The low pressure within the first chamber 302 and second chamber 306 can be, for example, as low as 10 milliTorr. Hence, processing in the first chamber 302 and second chamber 306 can be at a low pressure. The controller can operate the gas delivery system 307 to introduce the process gas into the first chamber 302, which can be evacuated by the vacuum processing system, to process the substrate 314. If implemented, plasma effluents can be introduced into the first chamber 302 from an RPS to process the substrate 314 during low pressure processing.

After high pressure processing in the first chamber 302, the controller can operate the exhaust system of the gas delivery system 307 to depressurize the first chamber 302 before the valve assembly 316 is opened. The pressure can be reduced to a low pressure such that the pressure differential between the first chamber 302 and the second chamber 306 can be minimized.

Additionally, while processing the substrate (e.g., with the valve assembly 316 open or closed and/or at high pressure or at low pressure), the controller can operate the heating elements 318 at the same or different temperatures during different processing. Further, the controller can operate the gas delivery system 307 to flow any appropriate gas during any processing (e.g., high pressure processing or low pressure processing).

When processing the substrate 314 in the multi-pressure processing chamber 300 is complete, the substrate 314 can be removed from the first chamber 302 using the transfer robot. To prepare for transfer of the substrate 314 out of the first chamber 302, the controller can operate the exhaust system of the gas delivery system 307 to depressurize the first chamber 302, if appropriate, before the valve assembly 316 is opened. In particular, before the substrate 314 is transferred out of the first chamber 302, the process gas can be exhausted from the first chamber 302 to reduce the pressure within the first chamber 302.

To enable the substrate 314 to be transferred out of the first chamber 302, the controller can open the valve assembly 316. The opened valve assembly 316 provides an opening through which the substrate 314 is moved to be transferred into the second chamber 306 and through the aperture 326. In particular, the opened valve assembly 316 enables the substrate 314 to be transferred directly into the second chamber 306, e.g., into the low pressure environment of the second chamber 306. The controller can then operate the transfer robot to transfer the substrate 314 to another chamber of a processing system, e.g., the processing system 100. For example, the substrate 314 is transferred to the appropriate processing chamber for further processing or to the load lock chamber to remove the substrate from the processing system.

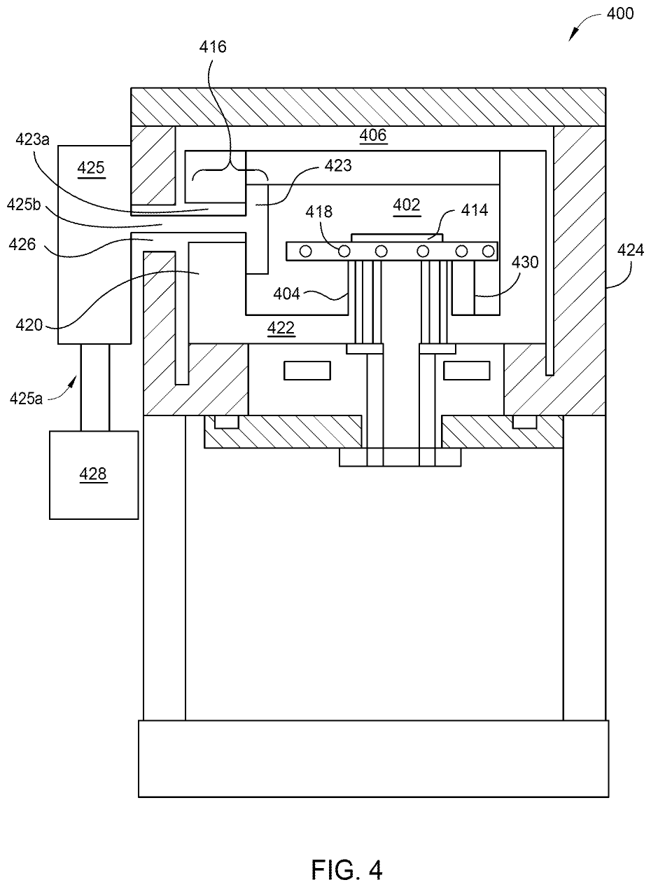

Referring to FIG. 4, in another example, a multi-pressure processing chamber 400 includes a first chamber 402, a pedestal 404, a second chamber 406, and a controller (not shown). The first chamber 402 is disposed within the second chamber 406 and may be considered an inner chamber, and the second chamber 406 may be considered an outer chamber. Further, the first chamber 402 can be configured to enable high pressure processing and may further be considered a high pressure chamber. The first chamber 402 and second chamber 406 may, in some instances, be fluidly coupled together and configured to enable low pressure processing. The multi-pressure processing chamber 400 is similar to the multi-pressure processing chamber 300 described with respect to FIG. 3; unless otherwise specified the various options and implementations are also applicable to the example of FIG. 4.

For example, the gas delivery system and the vacuum processing system of the multi-pressure processing chamber 400 are operated in a similar manner to maintain the low and high pressure environments for a substrate 414 processed using the multi-pressure processing chamber 400. The second chamber 406 can be defined by volume between inner walls 420 and outer walls 424. In addition, the substrate 414 is also supportable on the pedestal 404 for processing within the first chamber 402. Again, the substrate 414 can sit directly on the pedestal 404, or sit on lift pins 430 that extend through the pedestal.

The multi-pressure processing chamber 400 differs from the multi-pressure processing chamber 300 of FIG. 3 in a few regards. First, inner walls 420 defining the first chamber 402 are not movable relative to a base 422 defining the first chamber 402. The pedestal 404 is thus fixed relative to the inner walls 420 and the base 422. In some examples, the pedestal 404 is fixed to the base 422 defining the first chamber 402.

Rather than being arranged in the inner walls 420 of the first chamber 402, as is the case for the one or more heating elements 318 of the example of FIG. 3, one or more heating elements 418 of the example depicted in FIG. 4 are arranged within the pedestal 404. The substrate 414 may thus be heated through contact with the pedestal 404.

The multi-pressure processing chamber 400 further includes a valve assembly 416 between the first chamber 402 and the second chamber 406 that, similar to the valve assembly 316 of FIG. 3, isolates the first chamber 402 from the second chamber 406. However, in contrast to the valve assembly 316, the valve assembly 416 is not formed by the inner walls 420 and the base 422 defining the first chamber 402, but rather includes an arm assembly 425 that has one or more components that are movable relative to the inner walls 420 of the first chamber 402.

In particular, the valve assembly 416 includes the arm assembly 425 and a valve door 423 configured to isolate and fluidly connect the first chamber 402 and the second chamber 406. An aperture 423a is through an inner wall 420 and is between the first chamber 402 and the second chamber 406. An arm 425b of the arm assembly 425 is positioned in the aperture 423a through the inner wall 420 while the valve door 423 is positioned within the first chamber 402. The valve door 423 is connected to the arm 425b at a position distal from the remainder of the arm assembly 425. As illustrated, the arm 425b further extends through an aperture 426 through an outer wall 424, and the remainder of the arm assembly 425 is positioned outside of the second chamber 406. The arm assembly 425 is driven by an actuator 428, which is connected to a drive shaft 425a of the arm assembly 425, that is also positioned outside of the second chamber 406. Movement of the drive shaft 425a, which is driven by the actuator 428, is translated by the arm assembly 425 into movement of the arm 425b. In other examples, the arm assembly 425 (e.g., including the drive shaft 425a) and the actuator 428 can be positioned within the second chamber 406.

The arm assembly 425 extends through the aperture 423a and is movable relative to the inner walls 420 so that the valve door 423 can be moved to a position in which it forms a seal with the inner walls 420. The actuator 428 drives the drive shaft 425a of the arm assembly 425, which translates the driving of the drive shaft 425a into movement of the arm 425b relative to the inner walls 420 and in a general direction that the aperture 423a extends through the inner wall 420. Movement of the arm 425b in this direction can cause the valve door 423 to engage the inner wall 420 (e.g., when the arm 425b is retracted) to thereby form a seal with the inner wall 420 and isolate the first chamber 402 from the second chamber 406, and can cause the valve door 423 to become displaced from the inner wall 420 (e.g., when the arm 425b is extended) to thereby fluidly connect the first chamber 402 and the second chamber 406 In particular, the valve door 423 can be or include a flange from the arm 425b that extends substantially parallel to the adjacent inner surface of the inner wall 420.

Like the valve assembly 316, the valve assembly 416 is movable between an open position and a closed position. When the valve assembly 416 is in the closed position, the arm 425b of the arm assembly 425 is retracted laterally such that the valve door 423 covers the aperture 423a and contacts one of the inner walls 420, thereby forming the seal to isolate the first chamber 402 from the second chamber 406. In particular, the arm 425b of the arm assembly 425 causes the valve door 423 (e.g., the flange) to contact an inner surface of the inner wall 420 defining the first chamber 402.

When the valve assembly 416 is in the open position, the arm 425b of the arm assembly 425 is extended laterally such that the valve door 423 is spaced laterally apart from the inner wall 420, e.g., the inner surface of the inner wall 420. The aperture 423a thus provides an opening that enables fluid communication between the first chamber 402 and the second chamber 406.

The controller can operate the multi-pressure processing chamber 400 in a manner similar to the process described with respect to the controller of the multi-pressure processing chamber 300 to transfer the substrate 414 into and out of the first chamber 402 and to process the substrate 414. In this process, to open and close the valve assembly 416, the controller can operate the actuator 428 to drive the arm assembly 425.

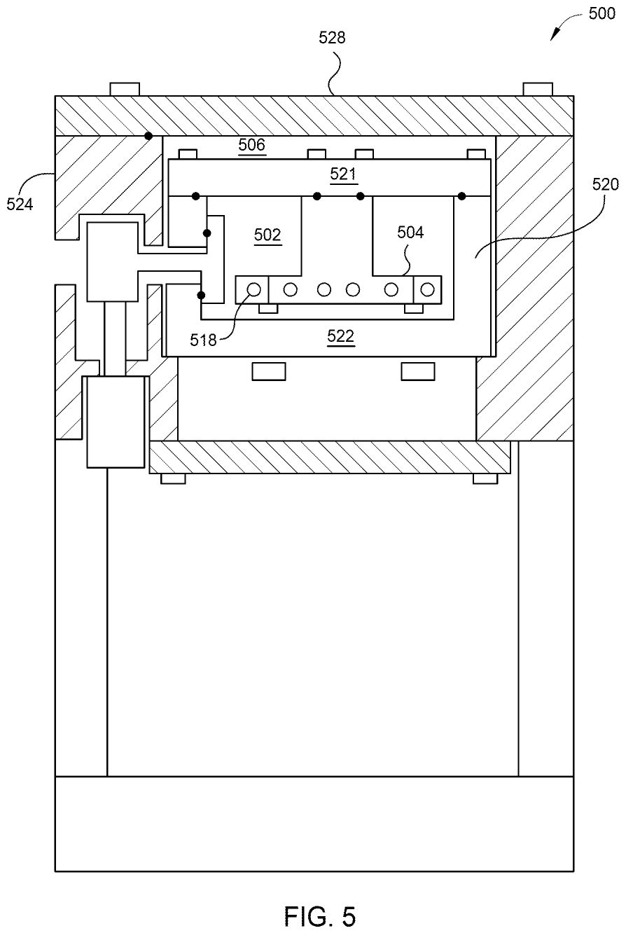

Referring to FIG. 5, in a further example, a multi-pressure processing chamber 500 includes a first chamber 502, a pedestal 504, a second chamber 506, and a controller (not shown). The multi-pressure processing chamber 500 is similar to the multi-pressure processing chamber 400 described with respect to FIG. 4; unless otherwise specified the various options and implementations are also applicable to this example.

For example, the gas delivery system and the vacuum processing system of the multi-pressure processing chamber 500 are operated in a similar manner to maintain the low and high pressure environments for a substrate (not shown) processed using the multi-pressure processing chamber 500. In addition, the substrate is also supportable on the pedestal 504 or lift pins for processing within the first chamber 502.

The multi-pressure processing chamber 500 differs from the multi-pressure processing chamber 400 of FIG. 4 in that the pedestal 504 is mounted to a ceiling 521 defining the first chamber 502 rather than to a base 522 defining the first chamber 502. Like the pedestal 504, the pedestal 504 is fixed relative to the walls 520, the ceiling 521, and the base 522. In addition, one or more heating elements 518 of the multi-pressure processing chamber 500 are arranged within the pedestal 504. To position the substrate on the pedestal 504 such that the substrate is supported on the pedestal 504, the substrate is inserted between plates of the pedestal 504. The one or more heating elements 518 are arranged relative to the plates such that, when the substrate is inserted into a slot defined by the plates of the pedestal 504, the one or more heating elements 518 can uniformly apply heat to the substrate.

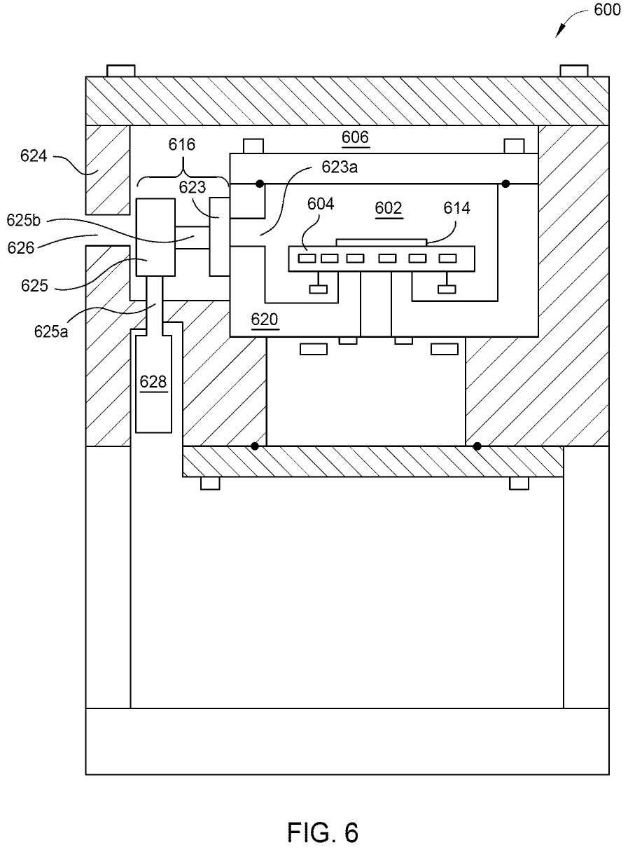

Referring to FIG. 6, in a further example, a multi-pressure processing chamber 600 includes a first chamber 602, a pedestal 604, a second chamber 606, and a controller (not shown). The multi-pressure processing chamber 600 is similar to the multi-pressure processing chamber 400 described with respect to FIG. 4; unless otherwise specified the various options and implementations are also applicable to this example.

For example, the gas delivery system and the vacuum processing system of the multi-pressure processing chamber 600 are operated in a similar manner to maintain the low and high pressure environments for a substrate 614 processed using the multi-pressure processing chamber 600. In addition, the substrate 614 is also supportable on the pedestal 604 for processing within the first chamber 602.

The multi-pressure processing chamber 600 differs from the multi-pressure processing chamber 400 of FIG. 4 in that a valve door 623 of a valve assembly 616 of the multi-pressure processing chamber 600 contacts an outer surface of an inner wall 620 defining the first chamber 602, rather than an inner surface of the inner wall 620, to cover an aperture 623a in the inner wall 620. Like the valve assembly 416, the valve assembly 616 operates to isolate the first chamber 602 from the second chamber 606. The valve assembly 616 can be positioned between the first chamber 602 and the second chamber 606.

The valve assembly 616 includes an arm assembly 625 and a valve door 623 disposed in the second chamber 606. An aperture 623a is through an inner wall 620 and is between the first chamber 602 and the second chamber 606. The valve door 623 is positioned outside of the first chamber 602. The arm assembly 625 is positioned outside of the first chamber 602 and within the second chamber 606. The arm assembly 625 does not extend through the slit 626.

An arm 625b of the arm assembly 625 is movable relative to the inner walls 620 so that the valve door 623 can be moved to a position in which it forms a seal with the inner walls 620. For example, the multi-pressure processing chamber 600 includes an actuator 628 operable to drive the arm assembly 625. The actuator 628 is coupled to the drive shaft 625a of the arm assembly 625, which is configured to drive to move the arm 625b of the arm assembly 625 relative to the inner walls 620.

Like the valve assembly 316, the valve assembly 616 is movable between an open position and a closed position. For example, when the valve assembly 616 is in the closed position, the arm 625b of the arm assembly 625 is laterally extended such that the valve door 623 contacts the inner wall 620 covering the aperture 623a, thereby forming the seal to isolate the first chamber 602 from the second chamber 606.

When the valve assembly 616 is in the open position, the arm 625b of the arm assembly 625 is laterally retracted such that the valve door 623 does not contact the inner wall 620 uncovering the aperture 623a. The aperture 623a thus provides an opening that enables fluid communication between the first chamber 602 and the second chamber 606.

The controller can operate the multi-pressure processing chamber 600 in a manner similar to the process described with respect to the controller of the multi-pressure processing chamber 300. In this process, to open and close the valve assembly 616, the controller can operate the actuator 628 to drive arm 625b of the arm assembly 625.

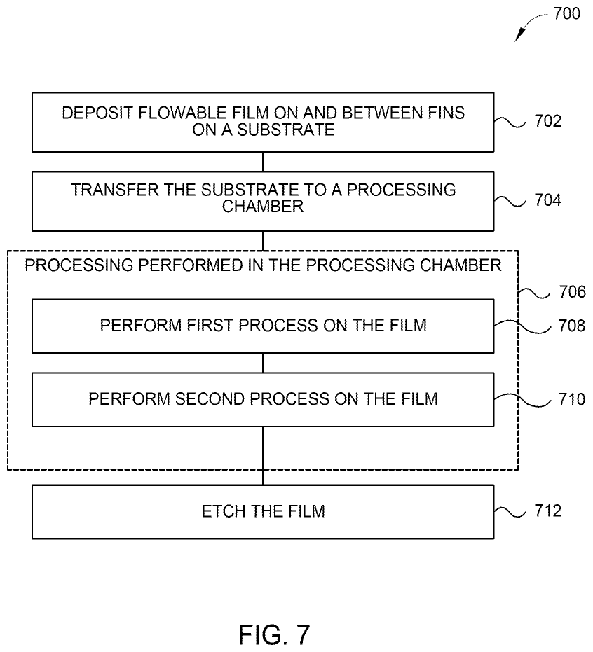

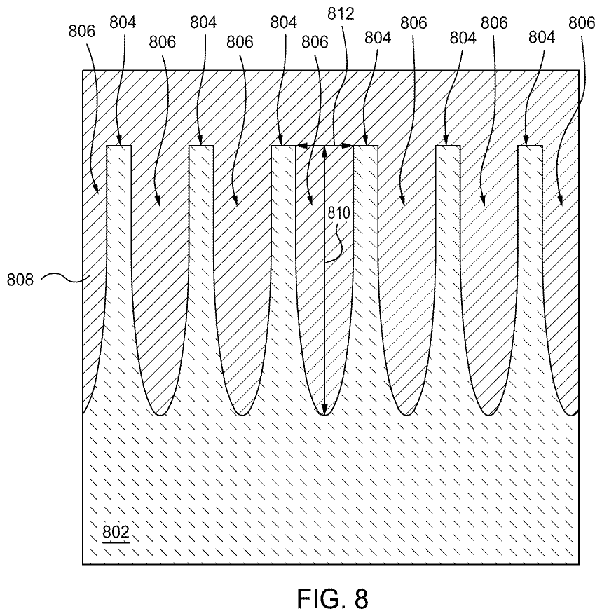

FIG. 7 is a flowchart of a method 700 for semiconductor processing according to some examples. FIGS. 8 through 10 are cross-sectional views of intermediate semiconductor structures illustrating aspects of the method 700 of FIG. 7 according to some examples. Examples described herein are in the context of forming isolation structures (e.g., shallow trench isolations (STIs)) between fins on a substrate. A person having ordinary skill in the art will readily understand various applications of aspects described herein to other contexts, and such variations are contemplated within the scope of other examples.

According to block 702 of FIG. 7, a flowable film is deposited on and between fins on a substrate. FIG. 8 illustrates a cross-sectional view of a flowable film 808 deposited on and between fins 804 on a substrate 802. To obtain the structure of FIG. 8, a substrate 802 is provided. The substrate 802 can be any appropriate semiconductor substrate, such as a bulk substrate, semiconductor-on-insulator (SOI) substrate, or the like. In some examples, the substrate 802 is a bulk silicon wafer. Examples of substrate sizes include 200 mm diameter, 350 mm diameter, 400 mm diameter, and 450 mm diameter, among others. Fins 804 are then formed on the substrate 802. The fins 804 can be formed by etching features, such as trenches 806 that extend into the substrate 802 such that each fin 804 is defined between a neighboring pair of features (e.g., trenches 806). Any appropriate patterning process can be implemented to form the features. The patterning process can include a multiple patterning process, such as self-aligned double patterning (SADP), lithography-etch-lithography-etch (LELE) double patterning, etc., to achieve a target pitch between fins 804. An example etch process to etch the trenches 806 includes a reactive ion etch (RIE) process or the like. Each trench 806 can have or form a high aspect ratio. The aspect ratio can be a ratio of the depth 810 of the trench 806 to the width 812 of the trench 806. An aspect ratio can be 10:1 or more. In some examples, one or more layers, such as a diffusion barrier layer, are formed on the fins 804, and the depth 810 and width 812 can be measured from an outer surface of the outermost layer.

The flowable film 808 is then deposited in the trenches 806 and on the fins 804. The flowable film 808 can be deposited by a FCVD process or spin-on, in some examples. For example, in a FCVD process, a flowable film 808 can be a silicon based dielectric that includes a high concentration of nitrogen and/or hydrogen. For example, in a FCVD process, precursors can be or include silyl-amines, such as H₂N(SiH₃), HN(SiH₃)₂, and N(SiH₃)₃, silane (SiH₄), or other similar precursors, which may be mixed with other gases, such as trisilylamine (N(SiH₃)₃), hydrogen (H₂), nitrogen (N₂), and/or ammonia (NH₃). The flowability of the flowable film 808 can permit the flowable film 808 to provide good gap filling, such as in high aspect ratio gaps (e.g., which may be formed by the trenches 806).

According to block 704, the substrate 802 having the flowable film 808 deposited thereon is then transferred to a processing chamber. The processing chamber is a multi-pressure processing chamber, such as any described above with respect to FIGS. 2 through 7. As example for context herein, the processing chamber of block 704 is the multi-pressure processing chamber 300 of FIG. 3. The processing chamber may be included in a processing system, such as the processing system 100 of FIG. 1.

For example, the substrate 802 is transferred by a front opening unified pod (FOUP) to a factory interface module 130, and at the factory interface module 130, the substrate 802 is transferred from the FOUP to a load lock chamber 128. Subsequent transfers and processing are performed in the processing system 100, e.g., without exposing the substrate 802 to an atmospheric ambient environment outside of the processing system 100 and without breaking a low pressure or vacuum environment maintained within the transfer apparatus of the processing system 100. The transfer robot 106 transfers the substrate 802 from the load lock chamber 128 into the first transfer chamber 102. The substrate 802 can thereafter be transferred to the processing chamber (e.g., multi-pressure processing chamber 300) by the transfer robot 106 if the multi-pressure processing chamber 300 is coupled to the first transfer chamber 102, or to a pass-through chamber 124 by the transfer robot 106 and subsequently from the pass-through chamber 124 to the multi-pressure processing chamber 300 by the transfer robot 108 if the multi-pressure processing chamber 300 is coupled to the second transfer chamber 104. In some examples, the deposition of the flowable film 808 can be in a processing chamber within the processing system. Hence, in such examples, the substrate 802 can be transferred into the processing system 100 before deposition of the flowable film 808 and can subsequently be transferred within the processing system 100 to the multi-pressure processing chamber 300. The valve assembly 316 of the multi-pressure processing chamber 300 is opened, and the transfer robot of the transfer chamber transfers the substrate 802 onto the pedestal 304, like described above.

According to block 706, processing is performed in the processing chamber, including a first process at block 708 followed by a second process at block 710. The second process at block 710 is different from the first process at block 708. Additional process may be performed in the processing chamber in other examples.

In some examples, the first process at block 708 forms more bonds and/or bonds that are more stable in the flowable film, and the second process at block 710 densifies, and may further create more stable bonds within, the stabilized film. Hence, the first process at block 708 includes stabilizing the flowable film, and the second process at block 710 includes densifying the stabilized film.

In some examples, the first process at block 708 and the second process at block 710 can be at a same or different pressure. In some examples, the first process at block 708 is at a pressure that is lower than a pressure of the second process at block 710. In some examples, the second process at block 710 is performed at a pressure within the processing chamber that is three orders of magnitude or more (e.g., four orders of magnitude or more) greater than a pressure within the processing chamber at which the first process at block 708 is performed. In some examples, the first process at block 708 is at a pressure that is greater than a pressure of the second process at block 710. As examples, the first process can be performed at a pressure in a range from 10 milliTorr to 100 Bar, and the second process can be performed at a pressure greater than or equal to 1 Bar, such as greater than or equal to 5 Bar.

In some examples, temperatures at which the first process and second process are performed are equal, while in other examples, the temperatures may differ. In some examples, a temperature of the first process at block 708 is less than a temperature of the second process at block 710. As examples, the temperature of the first process at block 708 can be in a range from 300° C. to 1000° C., and the temperature of the process at block 710 can be in a range from 300° C. to 1000° C., which temperature may be equal to, less than, or greater than the temperature of the first process at block 708. As examples, the temperature of the first process at block 708 can be in a range from 100° C. to 300° C., and the temperature of the process at block 710 can be in a range from 300° C. to 1000° C.

In some examples, a process gas composition (e.g., which may be a single gas or a mixture of gases) flowed for the first process at block 708 differs from a process gas composition flowed for the second process at block 710. Examples for the first process and second process are described below.

In some examples, the first process at block 708 is a conversion process in addition to being a stabilization process. The conversion and stabilization process converts the flowable film 808 to have another dielectric composition. For example, the conversion process can convert a silicon based dielectric that includes a high concentration of nitrogen and/or hydrogen deposited by a FCVD process into silicon oxide. The conversion process can be an oxidation process.

In some examples, the oxidation process is a thermal oxidation process or a plasma oxidation process. In a thermal oxidation process, an oxygen-containing process gas, such as oxygen gas (O₂), ozone gas (O₃), nitrous oxide (N₂O), nitric oxide (NO), or a combination thereof, can be flowed in the processing chamber. The oxygen-containing process gas can be continuously flowed into the processing chamber, or can be flowed into the processing chamber until a desired pressure is achieved and ceased, where the pressure is maintained thereafter during the oxidation process. The flow rate of the oxygen-containing process gas can be in a range from about 5 sccm to about 200 slm, for example. During the thermal oxidation process, the pressure within the processing chamber can be maintained at a pressure between 10 milliTorr and 100 Bar. The thermal oxidation process can be performed at a temperature greater than 300° C., such as in a range from about 300° C. to about 1000° C. In a plasma oxidation process, a plasma is ignited in a RPS using an oxygen-containing process gas, such as oxygen gas (O₂), ozone gas (O₃), nitrous oxide (N₂O), nitric oxide (NO), or a combination thereof. Oxygen-containing plasma effluents are flowed in the processing chamber. A RF power source of the RPS can have a frequency in a range from about 2 MHz to about 40 MHz, such as 13.56 MHz, and can have a power in a range from about 50 W to about 3000 W. Flowing of gas, a temperature, and pressure in the plasma oxidation process can be like previously described for the thermal oxidation.

In some examples, the first process at block 708 is a stabilization process that does not significantly affect the composition of the flowable film. For example, the stabilization process can substantially maintain a composition of a silicon based dielectric that includes a high concentration of nitrogen and/or hydrogen deposited by a FCVD process.

In some examples, the stabilization process is a thermal process or a plasma process. In a thermal process, an ammonia-containing process gas, such as ammonia gas (NH₃), can be flowed in the processing chamber. The ammonia-containing process gas can be continuously flowed into the processing chamber, or can be flowed into the processing chamber until a desired pressure is achieved and ceased, where the pressure is maintained thereafter during the thermal process. The flow rate of the ammonia-containing process gas can be in a range from about 5 sccm to about 200 slm, for example. During the thermal process, the pressure within the processing chamber can be maintained at a pressure between 10 milliTorr and 100 Bar. The thermal process can be performed at a temperature greater than 300° C., such as in a range from about 300° C. to about 1000° C. In a plasma process, a plasma is ignited in a RPS using an ammonia-containing process gas, such as ammonia gas (NH₃). Nitrogen-containing plasma effluents and/or hydrogen-containing plasma effluents are flowed in the processing chamber. A RF power source of the RPS can have a frequency in a range from about 2 MHz to about 40 MHz, such as 13.56 MHz, and can have a power in a range from about 50 W to about 3000 W. Flowing of gas, a temperature, and pressure in the plasma process can be like previously described for the stabilization without a plasma.

The first process at block 708 can be performed in the multi-pressure processing chamber 300 while the valve assembly 316 remains in an open or closed position, e.g., depending on a pressure at which the first process is performed. The valve assembly 316 can remain open for low pressure processing, or can be closed for high pressure processing. The oxygen-containing process gas or ammonia-containing process gas can be flowed through the gas delivery system 307 and evacuated through the second chamber 306 by the vacuum processing system. The heating elements 318 can maintain the temperature in the first chamber 302 during the first process.

In some examples, the second process at block 710 is a densification process. The densification process increases a density of the dielectric material that was stabilized and/or converted from the flowable film 808. For example, the densification process can increases a density of the silicon oxide, which was converted from the silicon based dielectric that included a high concentration of nitrogen and/or hydrogen deposited by a FCVD process. The densification process may additionally further convert the stabilized film to another dielectric composition (e.g., silicon oxide). The densification process can catalyze reactions that form Si—O—Si bonds. The densification process can be an anneal process.

In some examples, the anneal process is a dry anneal process or a steam anneal process. The dry anneal process can be performed at a temperature greater than 300° C., such as in a range from about 300° C. to about 1000° C. In the dry anneal process, a process gas, such as ammonia gas (NH₃), nitrous oxide (N₂O), nitric oxide (NO), or the like, can be flowed in the processing chamber. The process gas can be continuously flowed into the processing chamber, or can be flowed into the processing chamber until a desired pressure is achieved and ceased, where the pressure is maintained thereafter during the dry anneal process. The flow rate of the process gas can be in a range from about 5 sccm to about 200 slm, for example. The dry anneal process can additionally be an oxidation process to further convert the film when the process gas includes an oxygen-containing gas, such as nitrous oxide (N₂O) and/or nitric oxide (NO). During the dry anneal process, the pressure within the processing chamber can be maintained at a high pressure, such as on the order of a Bar, such as about 1 Bar or more, or more specifically, about 5 Bar or more.

The steam anneal process can be performed at a temperature greater than 300° C., such as in a range from about 350° C. to about 1000° C. In the steam anneal process, steam (H₂O) with or without another process gas, like ammonia gas (NH₃), nitrous oxide (N₂O), nitric oxide (NO), or a combination thereof, can be flowed in the processing chamber. The steam with or without a process gas can be continuously flowed into the processing chamber, or can be flowed into the processing chamber until a desired pressure is achieved and ceased, where the pressure is maintained thereafter during the steam anneal process. The flow rate of the steam with or without a process gas can be in a range from about 5 sccm to about 200 slm, for example. The steam anneal process can additionally be an oxidation process to further convert the film. During the steam anneal process, the pressure within the processing chamber can be maintained at a high pressure, such as on the order of a Bar, such as about 1 Bar or more, or more specifically, about 5 Bar or more.

The second process at block 710 can be performed in the multi-pressure processing chamber 300 while the valve assembly 316 is in an open or closed position, e.g., depending on a pressure at which the first process is performed. The process gas (e.g., including steam) can be flowed through the gas delivery system 307, which can establish and maintain the high pressure. The heating elements 318 can maintain the temperature in the first chamber 302 during the second process.

In further examples, the first process at block 708 is a conversion process in addition to a stabilization process. The conversion and stabilization process converts the flowable film 808 to have another dielectric composition, like described above. The conversion process can be an oxidation process. In some examples, the oxidation process is a steam oxidation process or a plasma oxidation process. In a steam oxidation process, steam (H₂O) can be flowed in the processing chamber. The steam can be continuously flowed into the processing chamber, or can be flowed into the processing chamber until a desired pressure is achieved and ceased, where the pressure is maintained thereafter during the steam oxidation process. The flow rate of the steam can be in a range from about 5 sccm to about 200 slm, for example. During the steam oxidation process, the pressure within the processing chamber can be maintained at a pressure less than 5 Bar. The pressure during the steam oxidation is less than the pressure of the second process at block 710. The steam process can be performed at a temperature greater than 100° C., such as in a range from about 100° C. to about 300° C. The temperature during the steam oxidation is less than the temperature of the second process at block 710. In a plasma oxidation process, a plasma is ignited in a RPS using steam (H₂O). Oxygen-containing plasma effluents and/or hydrogen-containing plasma effluents are flowed in the processing chamber. A RF power source of the RPS can have a frequency in a range from about 2 MHz to about 40 MHz, such as 13.56 MHz, and can have a power in a range from about 50 W to about 3000 W. Flowing of steam, a temperature, and pressure in the plasma oxidation process can be like previously described for the steam oxidation.

Table 1 below summarizes different combinations of processes according to some examples. An example is contained within a respective row in Table 1. Different combinations can be implemented. Additional processes can be performed, such as by repeating the first and second processes.

TABLE 1

| | First Process | Second Process |
|---|---|---|
| Ex. (1) | Process gas: O₂, O₃, N₂O, NO, or a | Process gas: H₂O, NH₃, N₂O, NO, or a |
| | combination thereof | combination thereof |
| | Pressure: 10 milliTorr to 100 Bar | Pressure: >= 1 Bar |
| | Temperature: 300° C. to 1000° C. | Temperature: 300° C. to 1000° C. |
| | Type: Gas or RPS | Type: Gas or RPS |
| Ex. (2) | Process gas: NH₃ | Process gas: H₂O, N₂O, NO, or a |
| | Pressure: 10 milliTorr to 100 Bar | combination thereof, any of which may |
| | Temperature: 300° C. to 1000° C. | additionally include NH₃ |
| | Type: Gas or RPS | Pressure: >= 1 Bar |
| | | Temperature: 300° C. to 1000° C. |
| | | Type: Gas or RPS |
| Ex. (3) | Process gas: H₂O | Process gas: H₂O, NH₃, N₂O, NO, or a |
| | Pressure: <= 5 Bar | combination thereof |
| | Temperature: 100° C. to 300° C. | Pressure: >= 1 Bar (or >= 5 Bar) |
| | Type: Gas or RPS | [Greater than pressure of First |
| | | Process] |
| | | Temperature: 300° C. to 1000° C. |
| | | [Greater than temperature of First |
| | | Process] |
| | | Type: Gas or RPS |

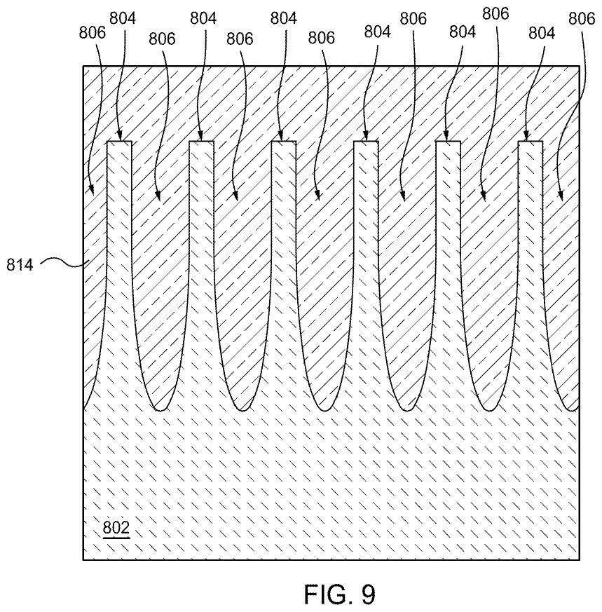

FIG. 9 illustrates a cross-sectional view of a converted and densified film 814, which was converted from the flowable film 808, on and between fins 804 on the substrate 802. In some examples, the flowable film 808 is converted from a silicon based dielectric that included a high concentration of nitrogen and/or hydrogen into a silicon dioxide, which was densified. In such examples, the converted and densified film 814 is a densified silicon oxide, which is a different material composition from the originally deposited flowable film 808.

According to block 712 of FIG. 7, the film that was processed at block 706 is etched. In some examples, after the processing of block 706, the substrate 802 is removed from the processing chamber by the transfer robot of the transfer chamber to which the processing chamber is coupled. For example, the substrate 802 can be removed from the first chamber 302 of the multi-pressure processing chamber 300 as described above. The substrate 802 can be transferred to another processing chamber within the processing system 100 or to a processing chamber of another processing system. The etch can be by any appropriate etch process. In some examples, the etch process is a wet etch, although a dry etch may also be implemented. Further, the wet etch can use dilute hydrofluoric acid (dHF), which can be selective to silicon oxide. In some examples, a 100:1 dHF solution was implemented to etch a converted and densified film of silicon oxide. The etch rate of the etch of block 706 can be more uniform and lower, which can be more easily controlled, as described above.

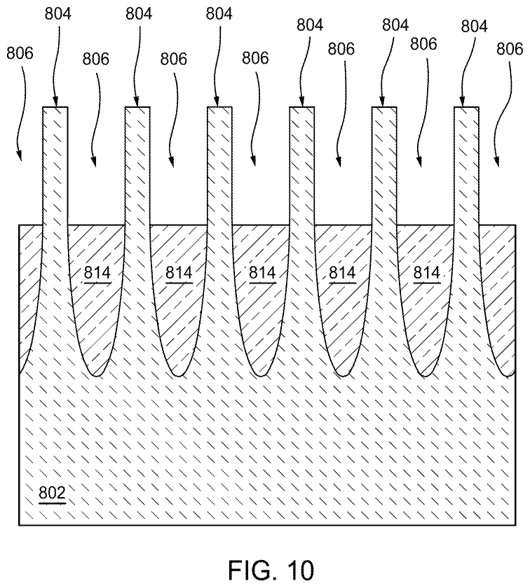

FIG. 10 illustrates a cross-sectional view of isolation structures (e.g., STIs) formed with the converted and densified film 814 in trenches 806 between fins 804 on the substrate 802, e.g., after etching the converted and densified film 814. As a result of the etch process, the fins 804 protrude from between neighboring isolation structures. Top surfaces of the isolation structures (e.g., top surface of the converted and densified film 814) can be recessed to any depth from top surfaces of the fins 804, and the illustration of FIG. 10 is merely an example.

The fins 804, with the isolation structures therebetween, can thereafter be used to form any appropriate device structure. For example, the fins 804 can be used to form FinFETs. A gate structure can be formed on and longitudinally perpendicularly to a fin 804. The gate structure can include a gate dielectric (e.g., a high-k gate dielectric) along surfaces of the fin, one or more work-function tuning layers on the gate dielectric, and a metal fill on the work-function tuning layer(s). The gate structure can define a channel region in the respective fin 804 underlying the gate structure. Source/drain regions (e.g., epitaxial source/drain regions) can be formed in the fin on opposing sides of the channel region. The gate structure, channel region, and source/drain regions together can form a FinFET.

While the foregoing is directed to various examples of the present disclosure, other and further examples may be devised without departing from the basic scope thereof, and the scope thereof is determined by the claims that follow.

1. A semiconductor processing system comprising:
a processing chamber; and
a system controller comprising a processor and memory, the memory storing instructions, that when executed by the processor, cause the processing chamber to:
perform a first process within the processing chamber on a substrate having thereon a film deposited by a flowable process, the first process comprising stabilizing bonds in the film to form a stabilized film; and
perform a second process within the process chamber on the stabilized film, the second process comprising densifying the stabilized film.

2. The semiconductor processing system of claim 1, wherein:
the first process is performed at a first pressure; and
the second process is performed at a second pressure greater than the first pressure.

3. The semiconductor processing system of claim 1, wherein:
the first process is performed including flowing a first process gas composition; and
the second process is performed including flowing a second process gas composition different than the first process gas composition.

4. The semiconductor processing system of claim 1, wherein:
the first process is performed at a first temperature; and
the second process is performed at a second temperature greater than the first temperature.

5. The semiconductor processing system of claim 1, wherein the first process further comprises:
converting the film to a different composition.

6. The semiconductor processing system of claim 1, wherein:
the first process is performed including flowing a first process gas including oxygen, ozone, nitrous oxide, nitric oxide, or a combination thereof; and
the second process is performed including flowing a second process gas including steam, ammonia, nitrous oxide, nitric oxide, or a combination thereof.

7. The semiconductor processing system of claim 1, wherein:
the first process is performed including flowing a first process gas including ammonia; and
the second process is performed including flowing a second process gas including steam, nitrous oxide, nitric oxide, or a combination thereof.

8. The semiconductor processing system of claim 1, wherein:
the first process is performed including flowing a first process gas including steam and is performed at a first pressure and at a first temperature; and
the second process is performed including flowing a second process gas including steam, ammonia, nitrous oxide, nitric oxide, or a combination thereof and is performed at a second pressure and at a second temperature, the second pressure being greater than the first pressure, the second temperature being greater than the first temperature.

9. The semiconductor processing system of claim 1, wherein the instructions, when executed by the processor, cause a plasma to be formed in a remote plasma source coupled to the processing chamber during the first process, the second process, or both the first process and the second process.

10. A semiconductor processing system comprising:
a processing chamber; and
a system controller coupled to the processing chamber, the system controller comprising a processor and memory, the memory storing instructions, that when executed by the processor, cause the processing chamber to:
stabilize bonds on a film deposited on a substrate by a flowable process using a first process within the processing chamber to form a stabilized film, wherein the first process is one of at least a thermal oxidation process, a plasma oxidation process, a stabilizing thermal process, or a stabilizing plasma process performed at a temperature of between about 300° C. and about 1000° C., or a steam oxidation process; and
perform a second process within the processing chamber at a temperature of between about 300° C. and about 1000° C. on the stabilized film.

11. The semiconductor processing system of claim 10, wherein the first process is performed at a pressure between 10 milliTorr and less than or equal to 1 Bar.

12. The semiconductor processing system of claim 10, wherein the second process is performed at a pressure greater than or equal to 1 Bar.

13. The semiconductor processing system of claim 10, wherein the second process is performed at a pressure greater than or equal to the first process.

14. The semiconductor processing system of claim 10, wherein the second process comprises:
densifying the stabilized film with an anneal process.

15. The semiconductor processing system of claim 10, wherein processing chamber comprises:
an inner processing chamber disposed within and in an outer processing chamber, the first process being performed in the outer processing chamber and the second process being performed in the inner processing chamber; and
a valve assembly comprising a first state wherein the valve assembly isolates the inner chamber from the outer chamber and a second state wherein the inner chamber and the outer chamber are in fluid communication.

16. A non-transitory computer-readable storage medium storing instructions that, when executed by a processor, cause a processing chamber to perform operations including:
controlling a first process within the processing chamber, the first process being performed on a substrate having thereon a film deposited by a flowable process, the first process comprising stabilizing bonds in the film to form a stabilized film; and
controlling a second process performed within the process chamber that densifies the stabilized film.

17. The non-transitory computer-readable storage medium of claim 16, wherein:
the first process is performed with flowing a first process gas composition; and
the second process is performed with flowing a second process gas composition different than the first process gas composition.

18. The non-transitory computer-readable storage medium of claim 16, wherein:
the first process is performed at a first pressure; and
the second process is performed at a second pressure greater than the first pressure.

19. The non-transitory computer-readable storage medium of claim 16, wherein the first process further includes converting the film to a different composition.

20. The non-transitory computer-readable storage medium of claim 16, wherein the first process is performed between 10 milliTorr and less than or equal to 1 Bar, is one of at least a thermal oxidation process, a plasma oxidation process, a stabilizing thermal process, or a stabilizing plasma process performed at a temperature of between about 300° C. and about 1000° C., or a steam oxidation process, and the second process is performed at greater than or equal to 1 Bar.
